(19) United States
(12) Patent Application Publication
(10) Pub. No.: US 2004/0057294 A1
(43) Pub. Date: Mar. 25, 2004

(54) Redundancy scheme for a memory array

(76) Inventor: Raj Kumar Jain, Singapore (SG)

Correspondence Address: Siemens Intellectual Property, Technology Consulting Pte Ltd., 166 Kallang Way, 6th Floor, Singapore, 349249, SG

(21) Appl. No.: 10/065,210

(22) Filed: Sep. 25, 2002

(51) Int. Cl. G11C 29/00

(52) U.S. Cl. 365/200

(57) ABSTRACT

An IC with a memory array comprises a redundancy unit. The redundancy unit includes a tag portion, an address portion, and a redundant memory cell portion. A comparator determines whether an address of a read or a write command matches with the address stored in the address portion of the redundancy unit and switches from the normal data path to the memory cell portion of the redundancy unit.

### BACKGROUND OF INVENTION

Integrated circuits having a memory array can comprise several hundred millions of memory cells. For example, due to defects in the semiconductor substrate which contains the memory cell array or due to contamination during the manufacturing of the memory device, it is difficult to produce a memory chip whose memory cells are a hundred percent defect free. The memory devices are tested after fabrication in order to determine functional and defective parts.

In the field of dynamic random access memories (DRAMs) the memory array comprises redundant cells and appropriate logic in order to replace defective cells with redundant cells. Since the memory cells are arranged in rows and columns, the DRAM array has redundant rows and/or columns in order to repair defective ones. If the number of redundant rows and/or columns is sufficient to repair all defective cells, the DRAM array can still be regarded as functional. Only if the defects within the memory cell array exceed the redundant circuitry, the chip must be discarded.

In particular, ICs with embedded static memory which is integrated together with, for example, a micro-processor, on the same die, conventional redundancy schemes used for DRAMs are difficult to implement. With increasing storage density, the probability of defective cells increases. For example, 5 to 20 bits per megabit of memory cells can be defective in SRAM ICs. The production yield of SRAMs with a higher number of memory cells is therefore low.

From the foregoing discussion, it is desirable to provide a redundancy scheme for ICs with memory array.

### SUMMARY OF INVENTION

The invention relates generally to ICs with a memory array. More particularly, the invention relates to redundancy for defective addresses in the memory array. The memory array comprises a plurality of memory cells. An input port of the memory array includes an address bus for receiving address information, a data-in path for receiving data to be written into the array. An output signal path is provided for outputting data from the array. The output signal path is coupled to the data-out path. A redundancy unit is provided. In one embodiment, the redundancy unit comprises at least one redundancy element with tag, address, data portions and a control circuit for generating an active signal indicating that a memory access is to a defective address. Additionally, read redundancy control and write redundancy control circuits are provided to facilitate transfer of information to or from the redundancy unit if the access is to a defective address.

### BRIEF DESCRIPTION OF DRAWINGS

FIG. 1 shows a block diagram of a portion of an IC in accordance with one embodiment of the invention; and

FIG. 2 shows a memory cell in accordance with one embodiment of the invention.

### DETAILED DESCRIPTION

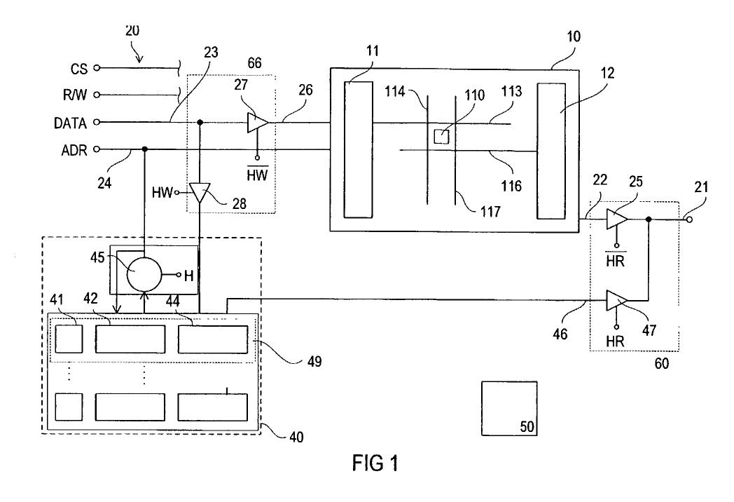

FIG. 1 shows an IC in accordance with one embodiment of the invention. The IC comprises an array 10 having a plurality of memory cells 110 arranged in rows and columns. The memory array includes an input port 20 which receives data, address, and command signals. For a write command, data is input through a data-in path 23. For a read command, data is output through a data-out path 21. Preferably, although not necessarily, both the data-in and data-out paths are of the same width. A particular memory cell 110 can be selected through a row decoder 111 which activates a word line 113. The data signal of memory cell 110 is output to bitline 114 and gated through the output signal path 22, which is coupled to the data-out path. Alternatively, the data path can be a bi-directional data path to facilitate both read and write accesses.

In one embodiment, a row comprises a plurality of words, in which a word has x memory cells, where x is a whole number greater or equal to 1. Preferably, x is equal to 2^{y}, where y is a whole number. More preferably, x is equal to the width of the data paths (e.g., data-in or data-out) of the memory array. Other values for x are also useful.

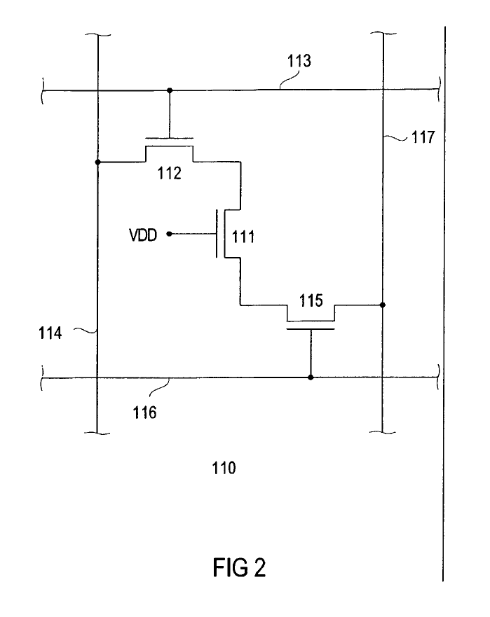

In one embodiment, the memory cells are static random access memory cells. Other types of memory cells, such as DRAM or multi-port cells, are also useful. For example, dual port memory cells, as the one shown in FIG. 2, can be used to form the memory array. Such memory cells are described in, for example, co-pending patent application, titled “Dual-Port Memory Cell”, U.S. Ser. No. 09/806,299 (attorney docket number: 98P 02816WOUS) which is herein incorporated by reference for all purposes. The information is stored in form of a charge in storage node 111. Storage node 111 is a transistor whose gate electrode is connected to a reference potential, for example, the positive supply voltage V_{DD}. One end of the drain/source path of the storage transistor 111 is connected to wordline 113 and to bitline 114 through a first selection transistor 112. Wordline 113 and bitline 114 are connected to a first access port A. The other end of the drain/source path of storage transistor 111 is connected to another wordline 116 and another bitline 117 through selection transistor 115. The other wordline 116 and bitline 117 are coupled to another port B of the memory device. Each port is associated with a row and a column decoder.

The storage node of memory cell 110 leaks its charge and must be refreshed within a retention time interval in order to have a sufficient amount of charge that can be detected by sense amplifiers. In one embodiment, the first port is accessed by the external system while the second port is hidden to the external system and used for internal operations. Preferably, the second port is used to refresh the memory cells so that the array has SRAM functionality although using dynamic memory cells internally. Alternatively, both ports can be accessed by the external system.

One of the memory cells of the memory cell array 10 can be defective due to various reasons, for example, particles and contamination during production, defects in the semiconductor substrate, misalignment of masks during fabrication, etc. In order to avoid the IC from being rejected as non-functional, a redundancy unit 40 is provided.

The redundancy unit 40 comprises at least one redundancy element. Preferably, the redundancy unit comprises a plurality of redundancy elements 49. A redundancy element is used to repair a defective element in the array. The granularity of an element depends on design specification. For example, a redundancy element can be configured for row or column redundancy. Other granularities, such as one memory cell can also be useful. Preferably, the granularity of an element is equal to the width of the data path. An element can also be designed with other granularities. The number of redundancy elements can be selected depending on process and/or design requirements. For example, a larger number of redundancy elements allow more defects to be repaired which increases yields. However, this is achieved at the cost of additional chip area, which increases chip size and manufacturing costs.

A redundant element, in one embodiment, comprises a tag portion 41, an address portion 42, and a data portion 44. The tag portion 41 indicates whether a redundancy element is used or programmed for redundancy or not. For example, a logical “1” indicates that the element is programmed for redundancy (e.g., data portion contains valid data for address stored in the address portion) and a logical “0” indicates that the element has not been programmed for redundancy.

To replace a defective element in the array, for example, memory cell 110, a redundancy element is programmed. This involves setting the tag portion to indicate that the redundancy element is programmed for redundancy (e.g., logical 1), programming the address portion with the address of the defective element (e.g., address of memory cell 110) and storing the data to be stored in the defective element in the data portion.

In one embodiment, the tag and address portions comprise fuse elements which can be programmed using laser blowable fuses. The laser fuses can be programmed during testing prior to packaging. Alternatively, electrical fuses can also be used for programming the fuse elements after packaging. The electrical fuses can be blown using an elevated current. Alternatively, anti-fuses can be used. Other types of fuses are also useful. In another embodiment, the tag and address portions can include read only memory. Other types of memory elements can also be useful.

The data portion, in one embodiment, comprises memory cells such as those used in the memory array. The data portion comprises sufficient memory cells to store the data which is to be store in the defective element. In one embodiment, the data portion comprises an array of redundant memory cells which can be accessed according to the redundancy architecture. The redundancy unit comprises a control circuit 43 to determine if a redundancy element has been programmed for redundancy. In one embodiment, the control circuit comprises a comparator 45 associated with each redundancy element.

During a memory access, the control circuit provides the address from the address bus to the comparators. In one embodiment, a comparator associated with a redundancy element with a tag portion programmed for redundancy compares the address of the access with the address stored in its respective redundancy element. In one embodiment, a comparator associated to an element which is not programmed for redundancy is disabled. Disabling comparators for non-programmed redundancy elements advantageously conserves power. If a comparator detects or determines a match between the address of the access with the address stored in the address portion, it generates an active redundancy signal H. Depending on whether the access is a read or write, data is read out from or stored into the data portion of the redundancy element associated with the comparator which generated the active redundancy signal.

In one embodiment, read and write redundancy control circuits 60 and 66 are provided to facilitate writing and reading information to and from the redundancy unit. The read redundancy control circuit is coupled to the redundancy unit and output signal path of the array. In one embodiment, an output port for outputting data from the data portion is coupled to the read redundancy control circuit. If a read access is associated with a defective address, the read redundancy control circuit causes data from the redundancy element corresponding to the defective address to be placed on the data-out path.

In one embodiment, the read redundancy control circuit comprises first and second switches 25 and 47. The first switch is coupled to the output signal path from the array and the second switch is coupled to the redundancy readout path 46. The output terminal of the switches can be commonly coupled to the data-out path. In one embodiment, the switches comprise tri-state drivers. Other types of switches or multiplexers are also useful.

When a defective address is read from, the first switch 25 is disabled and the second switch 47 is enabled. This decouples the output signal path from the array and couples the readout path of the redundancy unit to the data-out path 21. As previously described, the comparator generates an active H signal which indicates that element associated with the current access is defective. In one embodiment, the switches are controlled by complementary signals HR and /HR derived from H. In one embodiment, the first switch is controlled by /HR and the second switch is controlled by HR. An active HR signal (e.g., logic 1) is generated when H is active for a read access (e.g., reading from a defective address).

The write redundancy control circuit is coupled to the redundancy unit and data-path of the array. If a write access is associated with a defective address, the write redundancy control circuit causes data from the data-in path to be written into the element associated with the defective address.

In one embodiment, the write redundancy control circuit comprises first and second switches 28 and 27. The first switch is coupled to the data-in path and the redundancy unit. In one embodiment, the first switch is coupled to the data-in path and the data portion of the redundancy unit. The second switch is coupled to the data-in path and the memory array. The second switch is coupled to the data-in path between the node coupling the first switch and the array. In one embodiment, the switches comprise tri-state buffers. Other types of switches or multiplexers are also useful. Alternatively, the second switch can be omitted or is integrated into the read enable control or decoding circuitry 11 of the array. For example, the read enable or decoding circuitry can disabled the activation of the wordlines, preventing access to the cells of the array.

When a defective address is written to, the first switch 28 is enabled and the second switch 27 is disabled. This couples the data-in path to the redundancy unit and decouples it from the array. In one embodiment, the switches are controlled by complementary signals HW and /HW. The control signals are derived from the output of the comparator. In one embodiment, the first switch is controlled by HW and the second switch is controlled by /HW. An active HW signal (e.g., logic 1) is generated when H is active for a write access (e.g., writing to a defective address).

The second switch of the write redundancy control circuit can be omitted. In this case, data is written in parallel into the memory cell array 10 and the redundancy unit 40. The redundancy unit 40 prevents reading from a defective memory cell. Using the switch 27 advantageously conserves power. In another embodiment of the invention, the control circuit is provided with a plurality of comparators, each associated with a respective group of redundancy elements. The control circuit also includes a counter. In one embodiment, each comparator is provided with a counter. The counter, for example, is a cycle counter. The counter is used to point to an element which is programmed for redundancy. The counter is incremented to point to the next programmed element until all elements have been compared or a match is found. After each access, the counter can be reset to point to the first programmed element of the group. In another embodiment, only one comparator is provided for the redundancy units. Providing comparators associated with a group of redundancy elements or one comparator for the redundancy unit is useful, for example, for application where the comparisons can be achieved within a memory access in order not to hinder access performance. Such arrangements are also useful where performance is not an issue or chip space overrides performance considerations.

The address portions 42 are filled with valid addresses in response to a test of the memory cell array 10. The address portions 42 can be permanently programmed, for example, by laser programming or electrical programming of fuses. It is also useful to use other types of programmable devices like EPROM cells. Preferably, the address portions 42 are volatile memory cells which store the addresses during operation. In this case, the testing of the memory device 10 is performed after each power up of the memory device. The sequencing of control signals during the test is realized by built-in self-test control unit 50. For example, the built-in self-test control unit 50 performs a cyclic redundancy test for all the memory cells and determines the addresses of the defective cells. When a defective cell is detected, the tag portion 41 within the redundancy device 40 is set to “1” and the address is stored in address portion 42. The cycle counter of the redundancy unit 40 is incremented to the next active row. The functional test is performed by unit 50 after each power up and can be repeated periodically or in response to the system controller during operation. Any memory cell that becomes defective during a lifetime by aging effects is hereby detected and replaced by a redundant cell in data portion 44 of redundancy unit 40. According to the preferred embodiment, a memory device with SRAM functionality is obtained with a dynamic redundancy scheme.

In order not to slow down the access time of the memory device by the redundancy operation during a data write operation the decoding operations are running in parallel to the operation of the comparator 45. The same parallelism can be maintained during a read operation in order not to introduce an additional delay.

While the invention has been particularly shown and described with reference to various embodiments, it will be recognized by those skilled in the art that modifications and changes may be made to the present invention without departing form the spirit and scope thereof. The scope of the invention should therefore be determined not with reference to the above description but with reference to the appended claims along with their full scope of equivalents.

1. An integrated circuit (IC) comprising:
an array of memory cells arranged in rows and columns;
an address bus for receiving addressing information;
a data-in path for receiving data during a write memory access;
a signal out path coupled to the memory array for outputting data during a read;
a data-out path coupled to the signal out path; and
a redundancy unit comprising,
at least one redundancy element having tag, address, and data portions, the tag portion indicates whether the redundancy element has been programmed for redundancy, the address portion contains a defective address if the redundancy element has been programmed for redundancy, and the data portion contains data associated with the defective address,
a control circuit for generating an active signal indicating that an access is associated with the defective address,
a read redundancy control circuit coupled to the output signal path and redundancy unit, and
a write redundancy control unit coupled to the data in path and redundancy unit.

2. The IC of claim 1 wherein the memory cells comprise SRAM cells.

3. The IC of claim 1 wherein the memory cells comprise DRAM cells.

4. The IC of claim 1 wherein the memory cells comprise multi-port DRAM cells.

5. The IC of claim 1 wherein the memory cells comprise multi-port DRAM cells with SRAM functionality.

6. The IC of claim 1 wherein the redundancy unit comprises a plurality of redundancy elements.

7. The IC of claim 6 wherein the control circuit comprises a comparator, the comparator compares the address of the memory access from the address bus and addresses in the redundancy elements and generates the active signal if there is a match with one address in one of the redundancy elements.

8. The IC of claim 7 wherein the read redundancy control circuit is activated when the active signal is generated and the memory access is a read access.

9. The IC of claim 8 wherein the read redundancy control circuit comprises:
a first read control switch coupled to the output signal path and data-out path; and
a second read control switch coupled to the redundancy unit and data-out path, when the read redundancy control circuit is activated, the first switch is disabled to decouple the output signal path from the data-out path and the second switch is enabled to couple the redundancy unit to the data-out path; and
when the read redundancy control circuit is deactivated, the first switch is enabled to couple the output signal path from the data-out path and the second switch is disabled to decouple the redundancy unit to the data-out path.

10. The IC of claim 7 wherein the write redundancy control circuit is activated when the active signal is generated and the memory access is a write access.

11. The IC of claim 10 wherein the write redundancy control circuit comprises:
a write control switch coupled to the data-in path and the redundancy unit;
when the write redundancy control circuit is activated, the write control switch is enabled to couple the data-in path to the redundancy unit; and
when the write redundancy control circuit is deactivated, the write control switch is disabled to decouple the data-in path from the redundancy unit.

12. The IC of claim 10 wherein the write redundancy control circuit comprises:
a first write control switch coupled to the data-in path and the redundancy unit;
a second write control switch coupled to the data-in path and the array;
when the write redundancy control circuit is activated, the first write control switch is enabled to couple the data-in path to the redundancy unit and the second write control switch is disabled to decouple the data-in path from the array; and
when the write redundancy control circuit is deactivated, the first write control switch is disabled to decouple the data-in path from the redundancy unit and the second write control switch is enabled to couple the data-in path to the array.

13. The IC of claim 1 wherein the control circuit comprises a comparator, the comparator compares the address of the memory access from the address bus and address in the at least one redundancy element and generates the active signal if there is a match with one address in one of the redundancy element.

14. The IC of claim 13 wherein the read redundancy control circuit is activated when the active signal is generated and the memory access is a read access.

15. The IC of claim 14 wherein the read redundancy control circuit comprises:
a first read control switch coupled to the output signal path and data-out path;
a second read control switch coupled to the redundancy unit and data-out path;
when the read redundancy control circuit is activated, the first switch is disabled to decouple the output signal path from the data-out path and the second switch is enabled to couple the redundancy unit to the data-out path; and
when the read redundancy control circuit is deactivated, the first switch is enabled to couple the output signal path from the data-out path and the second switch is disabled to decouple the redundancy unit to the data-out path.

16. The IC of claim 13 wherein the write redundancy control circuit is activated when the active signal is generated and the memory access is a write access.

17. The IC of claim 16 wherein the write redundancy control circuit comprises:
a write control switch coupled to the data-in path and the redundancy unit;
when the write redundancy control circuit is activated, the write control switch is enabled to couple the data-in path to the redundancy unit; and
when the write redundancy control circuit is deactivated, the write control switch is disabled to decouple the data-in path from the redundancy unit.

18. The IC of claim 16 wherein the write redundancy control circuit comprises:
a first write control switch coupled to the data-in path and the redundancy unit;
a second write control switch coupled to the data-in path and the array;
when the write redundancy control circuit is activated, the first write control switch is enabled to couple the data-in path to the redundancy unit and the second write control switch is disabled to decouple the data-in path from the array; and
when the write redundancy control circuit is deactivated, the first write control switch is disabled to decouple the data-in path from the redundancy unit and the second write control switch is enabled to couple the data-in path to the array.

19. The IC of claim 1 further comprising a test control unit performing a test to determine defective addresses.

20. The IC of claim 19, wherein the test is performed during the initialization of the IC.
